(19) United States
(12) Patent Application Publication
(10) Pub. No.: US 2007/0272966 A1
(43) Pub. Date: Nov. 29, 2007

(54) Nonvolatile semiconductor memory device and method of fabricating the same

(76) Inventors: Daisuke Nishida, Yokohama-shi (JP); Katsuaki Natori, Yokohama-shi (JP); Akihito Yamamoto, Naka-gun (JP); Masayuki Tanaka, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/802,292

(22) Filed: May 22, 2007

(30) Foreign Application Priority Data
May 24, 2006 (JP) 2006-144581

(51) Int. Cl. H01L 29/76

(52) U.S. Cl. 257/314

(57) ABSTRACT

A method of fabricating a nonvolatile semiconductor memory device includes forming a first dielectric layer on a major surface of a semiconductor substrate, forming a floating gate electrode layer on the first dielectric layer, and forming a second dielectric layer, which includes a metal oxide film or a stacked film thereof, on the floating gate electrode layer. The method of fabricating the nonvolatile semiconductor memory device further includes forming a control gate electrode layer on the second dielectric layer by using a material including silicon having no silicon (Si)-hydrogen (H) bond.

### CROSS-REFERENCE TO RELATED APPLICATIONS

This application is based upon and claims the benefit of priority from prior Japanese Patent Application No. 2006-144581, filed May 24, 2006, the entire contents of which are incorporated herein by reference.

### BACKGROUND OF THE INVENTION

1. Field of the Invention

The present invention relates to a nonvolatile semiconductor memory device including a high-dielectric-constant inter-poly dielectric film, and a method of fabricating the nonvolatile semiconductor memory device.

2. Description of the Related Art

In next-generation nonvolatile semiconductor memory devices, the inter-cell distance will become smaller than in the conventional devices. Thus, in an inter-poly dielectric film which is formed between a charge accumulation layer and a control electrode layer, it will become impossible to realize an increase in area by making use of a three-dimensional structure which has been adopted in a conventional ONO film (i.e. a three-layer stacked film of a silicon oxide film/silicon nitride film/silicon oxide film).

Hence, in order to realize the next-generation nonvolatile semiconductor memory device, it is necessary to use, as an inter-poly dielectric film, an dielectric film which has a higher dielectric constant than in the prior art (see, e.g. Jpn. Pat. Appln. KOKAI Publication No. 2004-186252). With the use of the high-dielectric-constant film, the capacitance can be increased without reducing the physical film thickness. Thereby, a large capacitance is realized without increasing leak current, and there is no need to use a three-dimensional structure. Moreover, since the three-dimensional structure need not be adopted, the fabrication process is simplified, the yield is improved, and, as a result, the performance of the device can be enhanced.

In the prior art, a polysilicon (Poly-Si) electrode, which becomes a control electrode, is formed on the inter-poly dielectric film by using silane (SiH₄). However, since silane is a reducing gas, oxygen in the inter-poly dielectric film, which is formed of, e.g. a metal oxide film, is extracted at the time of forming the polysilicon electrode, and oxygen deficiency occurs. If oxygen deficiency occurs, such a problem arises that a leak current from the inter-poly dielectric film, to which a high voltage is applied, cannot fully be suppressed.

### BRIEF SUMMARY OF THE INVENTION

According to a first aspect of the present invention, there is provided a method of fabricating a nonvolatile semiconductor memory device, comprising: forming a first dielectric layer on a major surface of a semiconductor substrate; forming a floating gate electrode layer on the first dielectric layer; forming a second dielectric layer, which includes a metal oxide film or a stacked film thereof, on the floating gate electrode layer; and forming a control gate electrode layer on the second dielectric layer by using a material including silicon having no silicon (Si)-hydrogen (H) bond.

According to a second aspect of the present invention, there is provided a nonvolatile semiconductor memory device comprising: a first dielectric layer formed on a major surface of a semiconductor substrate; a floating gate electrode layer formed on the first dielectric layer; a second dielectric layer which is formed on the floating gate electrode layer and includes a metal oxide film or a stacked film thereof; and a control gate electrode layer which is formed on the second dielectric layer and is formed of polysilicon including a halogen element.

According to a third aspect of the present invention, there is provided a nonvolatile semiconductor memory device comprising: a first dielectric layer formed on a major surface of a semiconductor substrate; a floating gate electrode layer formed on the first dielectric layer; a second dielectric layer which is formed on the floating gate electrode layer and includes a metal oxide film or a stacked film thereof; and a control gate electrode layer which is formed on the second dielectric layer and is formed of polysilicon including carbon.

### BRIEF DESCRIPTION OF THE SEVERAL VIEWS OF THE DRAWING

FIG. 1 is a cross-sectional view illustrating a fabrication process step of a nonvolatile semiconductor memory device according to an embodiment of the present invention;

FIG. 2 is a cross-sectional view illustrating a fabrication step of the nonvolatile semiconductor memory device following the step shown in FIG. 1;

FIG. 3 is a cross-sectional view illustrating a fabrication step of the nonvolatile semiconductor memory device following the step shown in FIG. 2;

FIG. 4 is a cross-sectional view illustrating a fabrication step of the nonvolatile semiconductor memory device following the step shown in FIG. 3;

FIG. 5 is a cross-sectional view illustrating a fabrication step of the nonvolatile semiconductor memory device following the step shown in FIG. 4;

FIG. 6 is a cross-sectional view illustrating a fabrication step of the nonvolatile semiconductor memory device following the step shown in FIG. 5;

FIG. 7 is a cross-sectional view illustrating a fabrication step of the nonvolatile semiconductor memory device following the step shown in FIG. 6;

FIG. 8 is a cross-sectional view illustrating a fabrication step of the nonvolatile semiconductor memory device following the step shown in FIG. 7;

FIG. 9 is a cross-sectional view, taken along line A-A′ in FIG. 8, illustrating a fabrication step of the nonvolatile semiconductor memory device following the step shown in FIG. 8;

FIG. 10 is a cross-sectional view illustrating a fabrication process of a nonvolatile semiconductor memory device, in which silane gas (SiH₄) is used; and

FIG. 11 is a cross-sectional view illustrating a fabrication process of a nonvolatile semiconductor memory device, in which tetrachlorosilane (SiCl₄) is used according to the present embodiment.

### DETAILED DESCRIPTION OF THE INVENTION

A method of fabricating a nonvolatile semiconductor memory device according to an embodiment of the present invention will now be described with reference to the accompanying drawings.

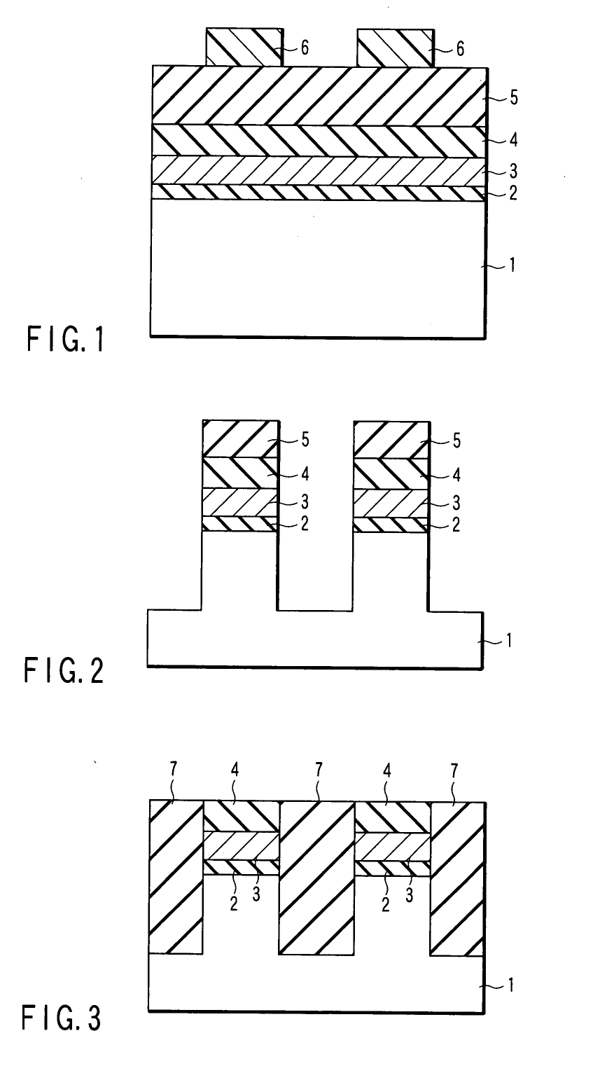

As shown in FIG. 1, a first dielectric film 2 (tunnel oxide film) with a thickness of about 1 nm to 15 nm is formed on a silicon substrate 1. A floating gate electrode layer 3 (charge accumulation layer) with a thickness of about 10 nm to 200 nm is formed of, e.g. polysilicon, on the first dielectric film 2 by chemical vapor deposition (CVD).

A silicon nitride film 4 with a thickness of about 50 nm to 200 nm is formed on the floating gate electrode layer 3 by chemical vapor deposition. A silicon oxide film 5 with a thickness of about 50 nm to 400 nm is formed on the silicon nitride film 4 by chemical vapor deposition. A photoresist 6 is coated on the silicon oxide film 5, and the photoresist 6 is patterned by photolithography. Thereby, a cross-sectional structure shown in FIG. 1 is obtained.

Using the photoresist 6 shown in FIG. 1 as an etching-resistant mask, the silicon oxide film 5 is etched. After the etching, the photoresist 6 is removed. Then, using the silicon oxide film 5 as a mask, the silicon nitride film 4 is etched. Subsequently, the floating gate electrode layer 3, first dielectric film 2 (tunnel oxide film) and silicon substrate 1 are etched. Thereby, trenches for isolation are formed, as shown in FIG. 2.

After the etching, a high-temperature post-oxidation step is performed to remedy damage in cross section due to the etching. Subsequently, as shown in FIG. 3, a buried insulation film 7, such as a silicon oxide film, with a thickness of 200 nm to 1500 nm, is filled in the isolation trenches. A density-increasing process for the buried dielectric film 7 is carried out by subjecting the buried dielectric film to high-temperature heat treatment in a nitrogen atmosphere or an oxygen atmosphere. Then, using the silicon nitride film 4 as s stopper, the surface of the obtained structure is planarized by chemical mechanical polishing (CMP). Thus, a cross-sectional structure shown in FIG. 3 is obtained.

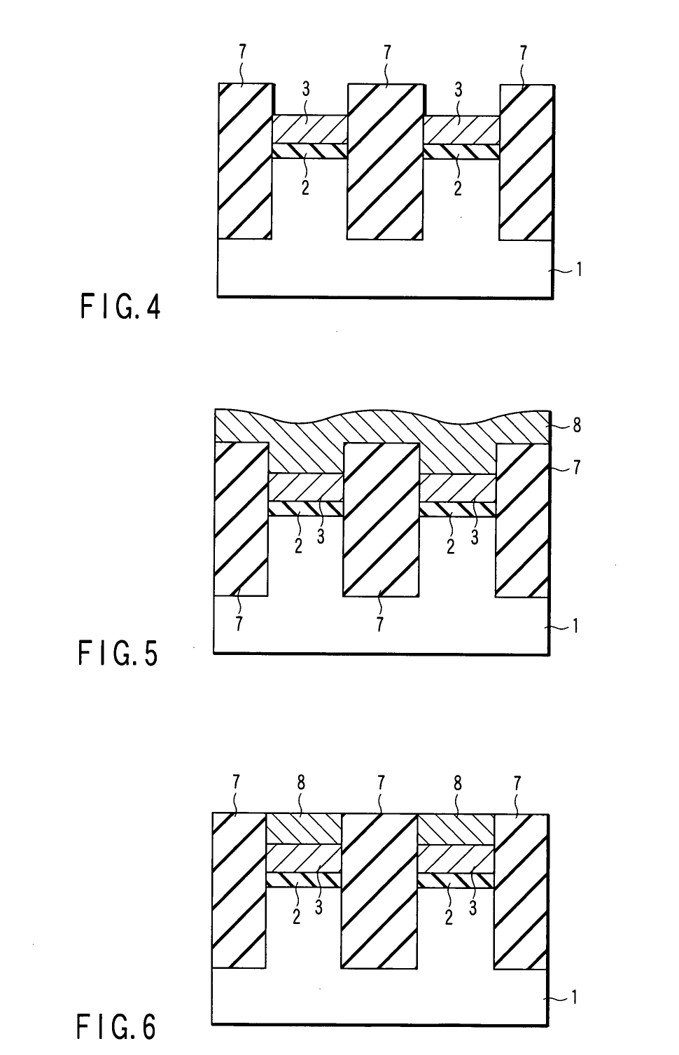

Thereafter, the silicon nitride film 4 is removed by hot phosphoric acid which enables etching with selectivity relative to the silicon oxide film 7. FIG. 4 shows a cross-sectional structure after the removal of the silicon nitride film 4.

In the above-described present embodiment, when the isolation trenches are formed, the stacked film of the silicon nitride film 4 and silicon oxide film 5 is used as the mask. Alternatively, if proper conditions are set for the film thickness and reactive ion etching, it is possible to use a single-layer silicon nitride film, a single-layer silicon oxide film, or other single-layer/multi-layer films, provided that these films are formed of materials that enable etching with selectivity relative to the silicon.

Subsequently, as shown in FIG. 5, an electrically conductive layer 8, which is formed of, e.g. polysilicon and will become a floating gate electrode as a whole together with the floating gate layer 3, is formed so as to cover the trenches that are made after the removal of the silicon nitride film 4 using a method with good step coverage. Then, using the buried dielectric film 7 as a stopper, the electrically conductive layer 8 is planarized by CMP, as shown in FIG. 6.

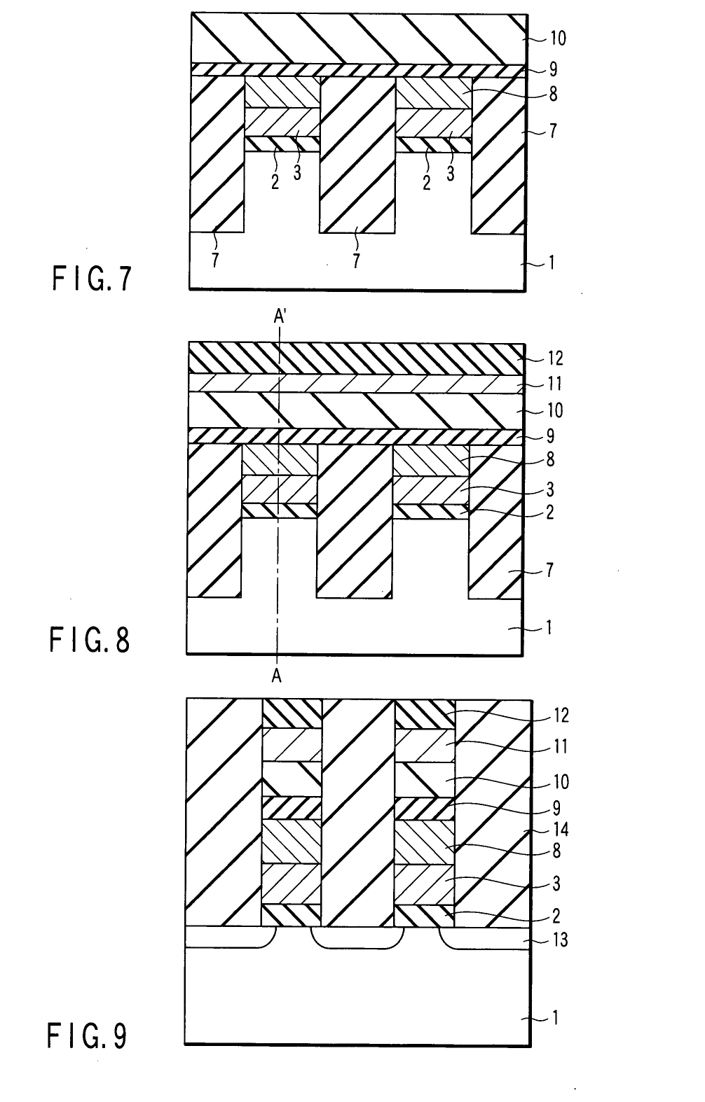

Following the above-described step, a second dielectric film 10 (inter-poly dielectric film) with a physical film thickness of about 1 nm to 40 nm, which has a higher dielectric constant than a silicon oxide film, is formed on the planarized surface, as shown in FIG. 7. In this case, an dielectric layer 9 with a thickness of about 0.1 to 5 nm is formed between the conductive layer 8, which constitutes the floating gate electrode, and the second dielectric film 10. The dielectric layer 9 is a silicon oxide film layer that is a native oxide film, or a silicon nitride film layer, or an oxynitride film layer.

Preferably, the high-dielectric-constant film, which is used as the second dielectric film 10, should be a film having a relative dielectric constant that is higher than a relative dielectric constant of 3.8 to 4 of a silicon oxide film (SiO₂ film) and is also higher than a relative dielectric constant of about 5 to 5.5 which is obtained with a conventional ONO film.

For example, a film that is usable as the second dielectric film 10 is a single-layer film or a multi-layer film, which is formed of one or more selected from the group consisting of a strontium oxide (SrO) film with a relative dielectric constant of about 6, an aluminum oxide (Al₂O₃) film with a relative dielectric constant of about 8, a magnesium oxide (MgO) film with a relative dielectric constant of about 10, an yttrium oxide (y₂O₃) film with a relative dielectric constant of about 16, a hafnium oxide (HfO₂) film with a relative dielectric constant of about 22, a zirconium oxide (ZrO₂) film with a relative dielectric constant of about 22, a tantalum oxide (Ta₂O₅) film with a relative dielectric constant of about 25, and a bismuth oxide (Bi₂O₃) with a relative dielectric constant of about 40.

Furthermore, the second dielectric film 10 may be formed of a composite film formed of one or more of the above-listed films and a silicon oxide film. This composite film may have a stacked structure of three or more layers. It is preferable, however, that the composite film, as a whole, have a relative dielectric constant that is greater than about 5 to 5.5.

In addition, the second dielectric film 10 may be formed of an dielectric film of a ternary compound, such as a hafnium aluminate (HfAlO) film. Specifically, a usable material is an oxide including at least one metal element selected from the group consisting of strontium (Sr), aluminum (Al), magnesium (Mg) yttrium (Y), hafnium (Hf), zirconium (Zr), tantalum (Ta) and bismuth (Bi).

For example, an aluminum oxide (Al₂O₃) film is formed by forming aluminum by performing reduced-pressure CVD at 300° C. to 600° C. using trimethyl aluminum (TMA) as a material gas, and then oxidizing the aluminum with an oxidizing agent (H₂O, ozone (O₃), dry O₂) Alternatively, aluminum may be formed by sputtering and then the aluminum may be oxidized with an oxidizing agent.

In the present embodiment, a hafnium aluminate (HfAlO) film was used as the second dielectric film 10. The hafnium aluminate film is formed, for example, by ALD (Atomic Layer Deposition) at 150° C. to 300° C. or reduced-pressure CVD at 400° C. to 600° C. In either case, a film is formed by alternately using tetraethylmethylamide hafnium (TEMAH) gas serving as hafnium material and trimethyl aluminum (TMA) gas serving as aluminum material, and the film is oxidized by using the above-mentioned oxidizing agent. Alternatively, hafnia (HfO₂) and alumina (Al₂O₃) may be alternately formed by ALD or CVD, and a stacked film of hafnium aluminate (HfAlO), as a whole, is formed. When hafnia (HfO₂) is formed, TEMAH and an oxidizing agent may be supplied at the same time.

In the next fabrication step, as shown in FIG. 8, a control gate electrode layer 11 with a thickness of 10 nm to 200 nm is formed of polysilicon on the second dielectric film 10. The control gate electrode layer 11 becomes a control electrode in the nonvolatile semiconductor memory device. A resist 12 is coated on the control gate electrode layer 11, and the resist is patterned by photolithography (not illustrated).

Using the resist pattern 12 as a mask, the control gate electrode layer 11, second dielectric film 10, dielectric layer 9, floating gate electrode 8, 3, and first dielectric film 2 are partly etched away, as shown in FIG. 9 that is a cross-sectional view taken along line A-A′ in FIG. 8. Source/drain regions 13 are formed by ion implantation, following which an isolation dielectric film 14 is buried and the structure shown in FIG. 9 is completed.

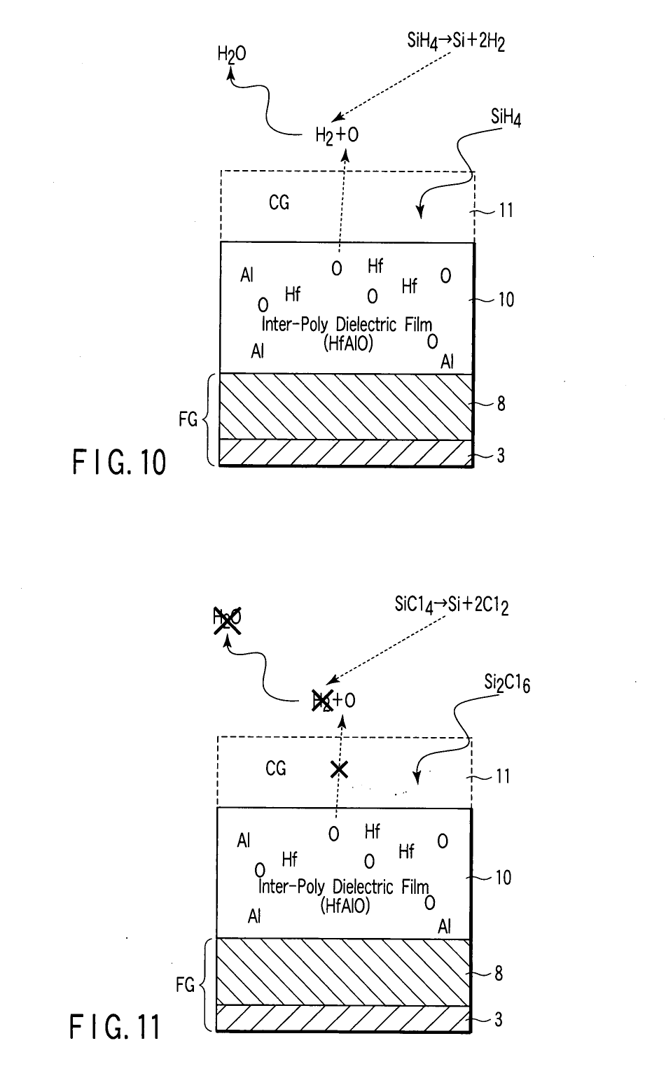

In the prior art, when polysilicon, which is used as the control electrode, is to be formed by vapor-phase growth, silane (SiH₄) is used. However, if a reducing gas such as silane is used, oxygen deficiency would occur in the second dielectric film 10 (hafnium aluminate film) as shown in FIG. 10.

Specifically, hydrogen (H₂), which is generated when silane gas is decomposed, bonds to oxygen in the second dielectric film 10, thus producing H₂O. As a result, oxygen deficiency occurs in the hafnium aluminate 10. FIG. 10 is a cross-sectional view showing only the upper part lying on the floating gate electrode layer 8, 3, with the depiction of the dielectric layer 9 being omitted.

In the present embodiment, the control gate electrode layer 11 is formed by reduced-pressure CVD at 500° C. to 700° C. by using, as a material gas, any one of, or a mixture of, a silicon material having no silicon (Si)-hydrogen (H) bond (e.g. tetramethylsilane (Si(CH₃)₄)) and a silicon material including no hydrogen (H) (e.g. tetrachlorosilane (SiCl₄), hexachlorodisilane (Si₂Cl₆), tetrafluorosilane (SiF₄), etc.).

Thereby, it becomes possible to suppress occurrence of damage due to oxygen deficiency in the second dielectric film 10 (hafnium aluminate), as is understood from FIG. 11 that shows the case in which tetrachlorosilane and hexachlorodisilane, for instance, are used.

This advantage of suppressing occurrence of damage due to oxygen deficiency in the second dielectric film 10 is most remarkably obtained in the case where the control gate electrode layer 11 is directly formed on the surface of the second dielectric film 10 by using the silicon material including no silicon (Si)-hydrogen (H) bond. However, a similar advantageous effect can be obtained even if a silicon oxide film (SiO₂ film) with a thickness of, e.g. about 2 nm is formed on the second dielectric film 10, and the control gate electrode layer 11 is formed with the silicon oxide film interposed between the control gate electrode layer 11 and the second dielectric film 10.

In the case where the control gate electrode layer 11 is formed by using the tetrachlorosilane (SiCl₄), hexachlorodisilane (Si₂Cl₆), tetrafluorosilane (SiF₄), etc., the surface of the second dielectric layer 10 is etched and formation of an interface layer is suppressed since fluorine (F) or chlorine (Cl) is included in the silicon material. In addition, since dangling bonds are terminated with fluorine (F) or chlorine (Cl), the bonds become more stable than in the case where the dangling bonds are terminated with hydrogen (H) that is easily released in a heat treatment step. As a result, a leak current flowing through the second dielectric layer 10 can be reduced, and the withstand voltage can be increased.

In this case, since the control gate electrode layer 11 is a polysilicon layer including a halogen element such as fluorine (F) or chlorine (Cl), anti-oxidation properties are improved and resistance can be decreased, in particular, in the range of a halogen element concentration of, e.g. 5E+18 to 5E+20 atoms/cm³. As a result, a decrease in power consumption and an increase in operation speed of the nonvolatile semiconductor memory device can be realized.

On the other hand, in the case where the control gate electrode layer 11 is formed by using tetramethylsilane (Si(CH₃)₄), a stable bond such as a Si—C bond, which does not easily alter, is formed since the silicon material includes carbon (C). As a result, formation of an interface layer is suppressed between the second dielectric layer 10 and control gate electrode layer 11, a leak current can be reduced, and a withstand voltage can be increased.

In this case, since the control gate electrode layer 11 is a polysilicon layer including carbon (C), chemical-resistance properties and hardness are improved, in particular, in the range of a carbon concentration of, e.g. 1E+18 to 2E+20 atoms/cm³. As a result, non-uniformity in fabrication in subsequent chemical treatment and processing steps can be reduced, and an improvement in yield can be expected.

In the present embodiment, the advantages are remarkable where the floating gate electrode layer has a decreased gate length, especially where the gate length is less than 60 nm.

The reason why this is so will be described. As a result of the miniaturization of elements, the second dielectric layer 10 serving as an inter-poly dielectric film is thin. This increases the relative film thickness ratio of a damage layer inside of the inter-poly dielectric film in which oxygen deficiency may be generated.

As can be the understood from the above, the less the gate length of the floating gate electrode layer is, the more remarkably the reduction of the dielectric constant can be suppressed. As a result, the withstand voltage can be remarkably increased, and the leak current can be remarkably decreased.

One aspect of the present invention can provide a nonvolatile semiconductor memory device in which a leak current via an inter-poly dielectric film is reduced, and a method of fabricating the same.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of fabricating a nonvolatile semiconductor memory device, comprising:
forming a first dielectric layer on a major surface of a semiconductor substrate;
forming a floating gate electrode layer on the first dielectric layer;
forming a second dielectric layer, which includes a metal oxide film or a stacked film thereof, on the floating gate electrode layer; and
forming a control gate electrode layer on the second dielectric layer by using a material including silicon having no silicon (Si)-hydrogen (H) bond.

2. The method according to claim 1, wherein the material including the silicon includes no hydrogen.

3. The method according to claim 1, wherein the material including the silicon is one of, or a mixture of, tetrachlorosilane (SiCl₄), hexachlorodisilane (Si₂Cl₆), tetrafluorosilane (SiF₄), and tetramethylsilane (Si(CH₃)₄).

4. The method according to claim 2, wherein the material including the silicon is one of, or a mixture of, tetrachlorosilane (SiCl₄), hexachlorodisilane (Si₂Cl₆) and tetrafluorosilane (SiF₄).

5. The method according to claim 1, wherein said forming the control gate electrode layer includes performing reduced-pressure CVD using the material including the silicon.

6. The method according to claim 1, wherein said forming the second dielectric layer includes forming a hafnium aluminate (HfAlO) film by ALD (Atomic Layer Deposition) or reduced-pressure CVD by alternately using tetraethylmethylamide hafnium (TEMAH) gas and trimethyl aluminum (TMA) gas.

7. The method according to claim 1, wherein said forming the second dielectric layer includes forming a hafnium aluminate (HfAlO) film by alternately forming hafnia (HfO₂) and alumina (Al₂O₃) by ALD (Atomic Layer Deposition) or CVD.

8. The method according to claim 1, wherein said forming the second dielectric layer includes forming an aluminum oxide (Al₂O₃) film by forming aluminum by reduced-pressure CVD using trimethyl aluminum (TMA) or sputtering and then oxidizing the aluminum.

9. A nonvolatile semiconductor memory device comprising:
a first dielectric layer formed on a major surface of a semiconductor substrate;
a floating gate electrode layer formed on the first dielectric layer;
a second dielectric layer which is formed on the floating gate electrode layer and includes a metal oxide film or a stacked film thereof; and
a control gate electrode layer which is formed on the second dielectric layer and is formed of polysilicon including a halogen element.

10. A nonvolatile semiconductor memory device comprising:
a first dielectric layer formed on a major surface of a semiconductor substrate;
a floating gate electrode layer formed on the first dielectric layer;
a second dielectric layer which is formed on the floating gate electrode layer and includes a metal oxide film or a stacked film thereof; and
a control gate electrode layer which is formed on the second dielectric layer and is formed of polysilicon including carbon.

11. The device according to claim 9, further comprising a silicon oxide film formed between the second dielectric layer and the control gate electrode layer.

12. The device according to claim 10, further comprising a silicon oxide film formed between the second dielectric layer and the control gate electrode layer.

13. The device according to claim 9, wherein a concentration of the halogen element in the control gate electrode layer is 5E+18 to 5E+20 atoms/cm³.

14. The device according to claim 10, wherein a concentration of the carbon in the control gate electrode layer is 1E+18 to 2E+20 atoms/cm³.

15. The device according to claim 9, wherein the second dielectric layer is a hafnium aluminate (HfAlO) film.

16. The device according to claim 10, wherein the second dielectric layer is a hafnium aluminate (HfAlO) film.

17. The device according to claim 9, wherein the second dielectric layer includes an oxide including at least one metal element selected from the group consisting of strontium (Sr), aluminum (Al), magnesium (Mg) yttrium (Y), hafnium (Hf), zirconium (Zr), tantalum (Ta) and bismuth (Bi).

18. The device according to claim 10, wherein the second dielectric layer includes an oxide including at least one metal element selected from the group consisting of strontium (Sr), aluminum (Al), magnesium (Mg) yttrium (Y), hafnium (Hf), zirconium (Zr), tantalum (Ta) and bismuth (Bi).

19. The device according to claim 9, wherein the floating gate electrode layer has a gate length less than 60 nm.

20. The device according to claim 10, wherein the floating gate electrode layer has a gate length less than 60 nm.
